(19) United States
(12) Patent Application Publication
(10) Pub. No.: US 2022/0102605 A1
(43) Pub. Date: Mar. 31, 2022

(54) DISPLAY PANEL AND METHOD FOR MANUFACTURING THE SAME

(71) Applicant: CHONGQING KONKA PHOTOELECTRIC TECHNOLOGY RESEARCH INSTITUTE CO., LTD., Chongqing (CN)

(72) Inventors: Jie FU, Chongqing (CN); CHENG-MING LIU, Chongqing (CN); Li-Wei KUNG, Chongqing (CN); Guojian ZHANG, Chongqing (CN)

(21) Appl. No.: 17/542,035

(22) Filed: Dec. 3, 2021

Related U.S. Application Data
(63) Continuation of application No. PCT/CN2020/118823, filed on Sep. 29, 2020.

(51) Int. Cl. H01L 33/62; H01L 25/075; H01L 23/00; H01L 33/00; H01L 33/58

(52) U.S. Cl. CPC H01L 33/62; H01L 25/0753; H01L 24/29; H01L 24/83; H01L 33/005; H01L 2933/0066; H01L 2224/29082; H01L 2224/83203; H01L 2224/83851; H01L 2924/12041; H01L 2933/0058; H01L 33/58

(57) ABSTRACT

The present disclosure relates to a display panel and a method for manufacturing the same. The method includes the following. A first adhesive layer and a second adhesive layer are disposed sequentially on a surface of a driving substrate, and the first adhesive layer includes conductive particles. Multiple light emitting units arranged in an array are adhered to one side of the second adhesive layer away from the driving substrate. The second adhesive layer is semi-cured. The first adhesive layer and the second adhesive layer are cured, and the multiple light emitting units are electrically connected with the driving substrate through the conductive particles.

### CROSS-REFERENCE TO RELATED APPLICATION(S)

This application is a continuation of International Application No. PCT/CN2020/118823, filed on Sep. 29, 2020, the entire disclosure of which is hereby incorporated by reference.

### TECHNICAL FIELD

The present disclosure relates to the technical field of display panel, and in particular to a display panel and a method for manufacturing the same.

### BACKGROUND

A micro light emitting diode (micro-LED) display panel is limited by the size of an LED thereof, and the LED has a P electrode and an N electrode each with the size of only a dozen microns. The traditional solder paste reflow technology is only applicable to a display panel in which the size of LEDs is greater than 100 μm and a distance between adjacent LEDs is greater than 400 μm, but is not applicable to the micro-LED display panel. Most existing micro-LED display panels adopt anisotropic conductive film (ACF) bonding and indium tin oxide (ITO) eutectic bonding. The ITO eutectic bonding requires a high degree of metal lattice matching, but ITO has a low affinity with most materials. Therefore, during the ITO eutectic bonding, vapor-deposition of aurum (Au) or copper (Cu) is usually needed, which is a complex process and relatively costly.

### SUMMARY

Considering disadvantages of the related art, in the present disclosure, a method for manufacturing a display panel is provided. The method includes the following. A first adhesive layer and a second adhesive layer are disposed sequentially on a surface of a driving substrate. The first adhesive layer includes conductive particles. Multiple light emitting units arranged in an array are adhered to one side of the second adhesive layer away from the driving substrate. The second adhesive layer is semi-cured. The first adhesive layer and the second adhesive layer are cured, where the multiple light emitting units are electrically connected with the driving substrate through the conductive particles.

An adhesiveness between a light emitting unit and the driving substrate can be increased with the method for manufacturing a display panel in the present disclosure. Therefore, the light emitting unit can be better aligned with an electrode on the driving substrate during mass transfer, thereby increasing accuracy of the position of the light emitting unit and thus a yield of display panel manufacturing.

Optionally, the first adhesive layer and the second adhesive layer are disposed sequentially on the surface of the driving substrate as follows, where the first adhesive layer includes the conductive particles. The first adhesive layer is pressed under a first condition onto a surface of the driving substrate on which electrodes are provided. The first adhesive layer includes the conductive particles. An adhesive is applied to a surface of the first adhesive layer away from the driving substrate and the adhesive is pre-cured, to form the second adhesive layer.

The adhesive for forming the second adhesive layer is pre-cured, which may decrease a fluidity of the adhesive, such that the formed second adhesive layer can have a more even thickness.

Optionally, the first condition includes a first temperature and a first pressure, the first temperature is between 60° C. and 80° C., and the first pressure is between 0.5 MPa and 1 MPa. Alternatively, the first condition includes an action of light and a first pressure, and the first pressure is between 0.5 MPa and 1 MPa.

Optionally, the second adhesive layer is semi-cured as follows. The multiple light emitting units are pressed under a second condition, to semi-cure the second adhesive layer.

Optionally, the second condition includes a second temperature and a second pressure, the second temperature is between 80° C. and 120° C., and the second pressure is between 0.8 MPa and 1.5 MPa. Alternatively, the second condition includes an action of light and a second pressure, and the second pressure is between 0.8 MPa and 1.5 MPa.

Under the second temperature, the second adhesive layer has a fluidity greater than the first adhesive layer, the squeezed second adhesive layer flows into gaps between the multiple light emitting units and fills the gaps, such that the semi-cured second adhesive layer is formed. As such, when the first adhesive layer is cured, a P electrode and an N electrode of the light emitting unit may have an improved ability to trap conductive particles. Therefore, the P electrode and the N electrode may trap more conductive particles and be better electrically connected with the driving substrate. At the same time, the first adhesive layer can form a shading structure after filling the gaps between the multiple light emitting units, which can prevent crosstalk of lateral light emitted by a light emitting unit to light emitted by an adjacent light emitting unit, such that preparation of a light-blocking portion is omitted.

Optionally, the second adhesive layer is semi-cured as follows. The multiple light emitting units are hot-pressed with a second pressure at a temperature where the first adhesive layer is in a rubbery state, to fill gaps between the multiple light emitting units with the second adhesive layer and form a semi-cured second adhesive layer.

Optionally, the first adhesive layer and the second adhesive layer are cured as follows. The multiple light emitting units are electrically connected with the driving substrate through the conductive particles. The multiple light emitting units are pressed under a third condition, to fill the gaps between the multiple light emitting units with the first adhesive layer and the second adhesive layer, and cure the first adhesive layer and the second adhesive layer, where the driving substrate is electrically connected with the multiple light emitting units through the conductive particles.

Optionally, the third condition includes a third temperature and a third pressure, the third temperature is between 150° C. and 220° C., and the third pressure is between 4.5 MPa and 7 MPa. Alternatively, the third condition includes an action of light and a third pressure, and the third pressure is between 4.5 MPa-7 MPa.

Optionally, during the curing, time for a temperature to rise to 90% of a third temperature is less than or equal to half of total time for the curing. As such, the P electrode and the N electrode may have an improved ability to trap the conductive particles, to be better electrically connected with the driving substrate. If the rising of the temperature is too slow, the P electrode and the N electrode may trap less conductive particles, which influences conductivity.

Optionally, the second adhesive layer has a light-blocking property, and the second adhesive layer has a melting temperature lower than the first adhesive layer. As such, when the first adhesive layer is cured, the P electrode and the N electrode may have an improved ability to trap the conductive particles. Therefore, the P electrode and the N electrode may trap more conductive particles and be better electrically connected with the driving substrate. At the same time, the first adhesive layer can form the shading structure after filling the gaps between the multiple light emitting units, which can prevent the crosstalk of the lateral light emitted by the light emitting unit to the light emitted by the adjacent light emitting unit, such that preparation of the light-blocking portion is omitted.

Based on a same inventive concept, a display panel is further provided in implementations of the present disclosure. The display panel includes a driving substrate, multiple light emitting units arranged in an array on one side of the driving substrate, and a shading structure located at a same side of the driving substrate as the multiple light emitting units. The shading structure is located in gaps between the multiple light emitting units and disposed around each of the multiple light emitting units. The shading structure includes conductive particles, and each of the multiple light emitting units is electrically connected with the driving substrate through the conductive particles.

In the present disclosure, the bonding between the light emitting units and the driving substrate of the display panel is achieved through an electrical connection via the conductive particles of the shading structure, such that the shading structure is formed when the light emitting units are bonded, thereby simplifying a manufacturing process of the display panel.

Optionally, the shading structure includes a connection portion and a light-blocking portion connected with the connection portion. The connection portion is disposed close to the driving substrate. The light-blocking portion is disposed away from the driving substrate. The connection portion includes the conductive particles and has anisotropic conductivity. The light-blocking portion has a light-blocking property.

Optionally, the light-blocking portion has a thickness between 4 μm and 7 μm.

Optionally, the connection portion has a thickness between 3 μm and 8 μm.

Optionally, electrical connection between the multiple light emitting units and the driving substrate is completed in a same process as forming the shading structure.

Optionally, the display panel is manufactured with the method for manufacturing a display panel.

### BRIEF DESCRIPTION OF THE DRAWINGS

In order to describe technical solutions of implementations of the present disclosure or the related art more clearly, the following will give a brief introduction to the accompanying drawings used for describing implementations or the related art. Apparently, the accompanying drawings described hereinafter are some implementations of the present disclosure. Based on these drawings, those of ordinary skill in the art can also obtain other drawings without creative effort.

FIG. 1 is a flow block diagram illustrating a method for manufacturing a display panel according to implementations of the present disclosure.

FIG. 2 is a flowchart illustrating a method for manufacturing a display panel according to implementations of the present disclosure.

FIG. 3 is a schematic structural diagram illustrating a display panel according to implementations of the present disclosure.

Description of reference numbers: 100—display panel; 10—driving substrate; 11—first electrode; 13—second electrode; 20—shading structure; 30—first adhesive layer/connection portion; 31—conductive particle; 50—second adhesive layer/light-blocking portion; 70—light emitting unit; 71—P electrode; 73—N electrode.

### DETAILED DESCRIPTION

In order to make the purposes, technical solutions, and advantages of the present disclosure clearer, the following will describe the present disclosure in detail with combination of accompanying drawings and implementations. It should be understood that, implementations described herein are merely for explaining, rather than limiting, the present disclosure.

It should be understood that directional relationship or positional relationship indicated by terms such as “center”, “longitudinal”, “lateral”, “length”, “width”, “thickness”, “on”, “under”, “front”, “back”, “left”, “right”, “vertical”, “horizontal”, “top”, “bottom”, “in”, “out”, “clockwise”, “anticlockwise”, and the like is directional relationship or positional relationship based on accompanying drawings and are only for the convenience of description and simplicity, rather than explicitly or implicitly indicate that apparatuses or components referred to herein must have a certain direction or be configured or operated in a certain direction and therefore cannot be understood as limitation on the present disclosure. In addition, terms “first”, “second”, and the like are only used for description and cannot be understood as explicitly or implicitly indicating relative importance or implicitly indicating the number of technical features referred to herein. Therefore, features restricted by terms “first”, “second”, and the like can explicitly or implicitly include at least one of the features. In the context of the present disclosure, unless stated otherwise, “multiple” refers to “at least two or more”.

Unless stated otherwise, in the present disclosure, terms “installing”, “coupling”, “connecting”, and the like referred to herein should be understood in broader sense. For example, coupling may be a fixed coupling, a removable coupling, or an integrated coupling, may be a mechanical coupling, an electrical coupling, and may be a direct coupling, an indirect coupling through a medium, or a communication coupling between two components or an interaction coupling between two components. For those of ordinary skill in the art, the above terms in the present disclosure can be understood according to specific situations.

A driving substrate and a light emitting unit cannot be firmly adhered to each other when a mass transfer process is performed on a current display panel. Therefore, the light emitting unit is prone to have an abnormal position, thereby reducing accuracy of mass transfer.

The method for manufacturing a display panel in the present disclosure includes the following. The first adhesive layer and the second adhesive layer are disposed sequentially on the surface of the driving substrate. The first adhesive layer includes conductive particles. The multiple light emitting units arranged in an array are adhered to one side of the second adhesive layer away from the driving substrate. The second adhesive layer is semi-cured. The first adhesive layer and the second adhesive layer are cured, where the multiple light emitting units are electrically connected with the driving substrate through the conductive particles. As such, an adhesiveness between the light emitting unit and the driving substrate can be increased. Therefore, the light emitting unit can be better aligned with the electrode on the driving substrate during mass transfer, thereby increasing accuracy of the position of the light emitting unit and thus the yield of the display panel manufacturing. At the same time, a color cast risk may be effectively decreased by using a retaining wall structure formed in the bonding process.

The solder paste reflow technology is only applicable to a display panel in which the size of light emitting diodes (LED) is greater than 100 μm and a distance between adjacent LEDs is greater than 400 μm, but is not applicable to a micro-LED display panel. Most existing micro-LED display panels adopt anisotropic conductive film (ACF) bonding and indium tin oxide (ITO) eutectic bonding. The ITO eutectic bonding requires a high degree of metal lattice matching, but ITO has a low affinity with most materials. Therefore, during the ITO eutectic bonding, vapor-deposition of aurum (Au) or copper (Cu) is usually needed, which is a complex process and relatively costly. An ACF material does not have adhesiveness before being main cured. The ACF material and the LED cannot be firmly adhered to each other during mass transfer. Therefore, the LED is prone to have an abnormal position, thereby reducing accuracy of mass transfer and increasing difficulty of repairing a thin film transistor (TFT) substrate.

Based on the above, a method for solving the above-mentioned technical problem is provided according to the present disclosure, which will be explained in detail in the following implementations.

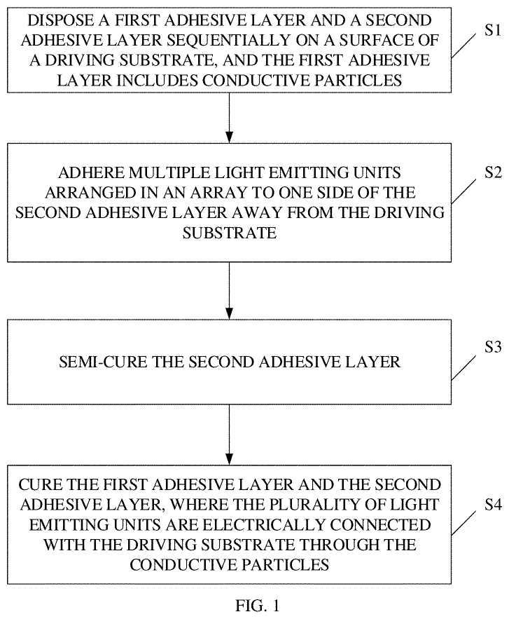

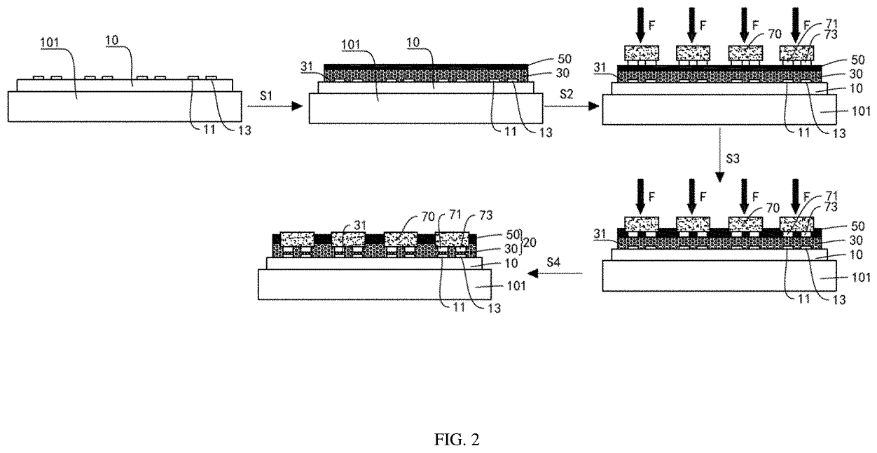

Referring to FIGS. 1 to 3, a method for manufacturing a display panel 100 is provided in implementations of the present disclosure. At S1, a first adhesive layer 30 and a second adhesive layer 50 are disposed sequentially on a surface of a driving substrate 10, and the first adhesive layer 30 includes conductive particles 31.

Specifically, the driving substrate 10 is a TFT array substrate. The driving substrate 10 is provided with first electrodes 11 and second electrodes 13 on the surface. The first electrodes 11 are electrically connected with source electrodes or drain electrodes of the TFT array substrate and arranged in an array. The second electrodes 13 are connected with common electrodes (low-level potential Vss) and arranged in an array. The first electrodes 11 and the second electrodes 13 are both ITO electrodes.

Optionally, the driving substrate 10 may be disposed on a supporting stage 101 during manufacturing the display panel 100. The driving substrate 10 may be disposed on the supporting stage 101 before disposing the first adhesive layer 30 and the second adhesive layer 50.

Optionally, the first adhesive layer 30 is an ACF which has conductivity in some directions and has no conductivity in other directions. In some implementations, the first adhesive layer 30 may be an adhesive with the conductive particles 31. The first adhesive layer 30 has a rubbery state. A temperature where the first adhesive layer 30 is in the rubbery state is closer to a semi-cured temperature of the second adhesive layer 50.

Optionally, the conductive particle 31 may have a particle diameter between 3 μm and 5 μm. That is, the particle diameter of the conductive particle 31 may have any value between 3 μm and 5 μm, such as 3 μm, 3.5 μm, 4 μm, 4.5 μm, or 5 μm.

Optionally, the second adhesive layer 50 is made of non-conductive paste (NCP) and has a light-blocking property. The second adhesive layer 50 has a melting temperature lower than the first adhesive layer 30. In some implementations, the second adhesive layer 50 may be a mixture of a curing agent and an epoxy resin material added with a black material such as carbon black or black paste dye. The second adhesive layer 50 has a semi-cured state, i.e., a B-stage. The second adhesive layer 50 is soluble and fusible in the B-stage. The second adhesive layer 50 transfers from the B-stage to a fully-cured state when further being cured by heating.

Optionally, the light-blocking property includes, but is not limited to, a property of preventing light penetration, such as reflecting light, absorbing light, or the like.

Specifically, the first adhesive layer 30 and the second adhesive layer 50 are disposed sequentially on the surface of the driving substrate 10 as follows, where the first adhesive layer 30 includes the conductive particles 31. At S11, the first adhesive layer 30 is pressed under a first condition onto a surface of the driving substrate 10 on which electrodes are provided.

Optionally, the first condition includes a first temperature and a first pressure, or the first condition includes an action of light and a first pressure.

Optionally, the first temperature is between 60° C. and 80° C., i.e., the first temperature may be any temperature between 60° C. and 80° C., such as 60° C., 65° C., 70° C., 75° C., or 80° C.

Optionally, the first pressure is between 0.5 MPa and 1 MPa, i.e., the first pressure may be any pressure between 0.5 MPa and 1 MPa, such as 0.5 MPa, 0.6 MPa, 0.75 MPa, 0.8 MPa, 0.9 MPa, or 1 MPa.

Optionally, the action of light may be an action of ultraviolet (UV) light.

At S12, an adhesive is applied to a surface of the first adhesive layer 30 away from the driving substrate 10 and is pre-cured, to form the second adhesive layer 50.

Specifically, the adhesive is sprayed to the surface of the first adhesive layer 30 away from the driving substrate 10 by using an ink jet printing (IJP) technology and is UV pre-cured, to form the second adhesive layer 50.

The adhesive for forming the second adhesive layer 50 is pre-cured with UV, which may decrease a fluidity of the adhesive, such that the formed second adhesive layer 50 can have a more even thickness.

At S2, multiple light emitting units 70 arranged in an array are adhered to one side of the second adhesive layer 50 away from the driving substrate 10.

Specifically, the multiple light emitting units 70 are adhered to one side of the second adhesive layer 50 away from the driving substrate 10 by using mass transfer, such that the multiple light emitting units 70 can be arranged in an array on the second adhesive layer 50. Each of the multiple light emitting units 70 includes a P electrode 71 and an N electrode 73. The light emitting unit 70 has a surface facing the driving substrate 10, where the P electrode 71 and the N electrode 73 are disposed on the surface. For each light emitting unit 70, the P electrode 71 has a position corresponding to the first electrode 11, and the N electrode 73 has a position corresponding to the second electrode 13.

Optionally, the light emitting unit 70 may be, but is not limited to, a micro-LED or a mini-LED.

At S3, the second adhesive layer 50 is semi-cured.

Optionally, the second adhesive layer 50 is semi-cured as follows. The multiple light emitting units 70 are pressed under a second condition, to semi-cure the second adhesive layer 50. The first adhesive layer 30 is in the rubbery state under the second condition.

Optionally, the second condition includes a second temperature and a second pressure, or the second condition includes an action of light and a second pressure.

Optionally, the second temperature is between 80° C. and 120° C., i.e., the second temperature may be any temperature between 80° C. and 120° C., such as 80° C., 85° C., 90° C., 95° C., 100° C., 105° C., 110° C., 115° C., or 120° C.

Optionally, the second pressure is between 0.8 MPa and 1.5 MPa, i.e., the second pressure may be any pressure between 0.8 MPa and 1.5 MPa, such as 0.8 MPa, 1.0 MPa, 1.1 MPa, 1.2 MPa, 1.3 MPa, or 1.5 MPa.

Optionally, the action of light may be an action of UV light. In this case, the first adhesive layer 30 and the second adhesive layer 50 may be made of a light-cured material.

Optionally, at the second temperature, the second adhesive layer 50 is in the B-stage, the first adhesive layer 30 gradually transfers from a cured state or a glassy state to the rubbery state, and the first adhesive layer 30 has a cured temperature lower than the second temperature.

That is, the semi-cured temperature of the second adhesive layer 50, i.e., the second temperature is higher than a glass transition temperature (Tg) of the first adhesive layer and lower than the cured temperature of the first adhesive layer.

Under the second temperature, the second adhesive layer 50 has a fluidity greater than the first adhesive layer 30, the squeezed second adhesive layer 50 flows into gaps between the multiple light emitting units 70 and fills the gaps, such that the semi-cured second adhesive layer 50 is formed. As such, when the first adhesive layer 30 is cured, the P electrode 71 and the N electrode 73 may have an improved ability to trap the conductive particles 31. Therefore, the P electrode 71 and the N electrode 73 may trap more conductive particles 31 and be better electrically connected with the driving substrate 10. At the same time, the first adhesive layer 30 can form a shading structure after filling the gaps between the multiple light emitting units 70, which can prevent crosstalk of lateral light emitted by a light emitting unit 70 to light emitted by an adjacent light emitting unit 70, such that preparation of a light-blocking portion 50 is omitted.

Optionally, in some implementations, each of the P electrode 71 and the N electrode 73 traps more than 5 conductive particles 31 on the surface facing the driving substrate 10, which is beneficial for the conduction between the P electrode 71 or the N electrode 73 and the driving substrate 10.

Optionally, in some implementations, during hot-pressing for semi-curing, a buffer layer is disposed on a surface of a hot-pressing head facing the multiple light emitting units 70. Alternatively, a buffer layer is disposed on a surface of the multiple light emitting units 70 away from the driving substrate 10.

Optionally, the buffer layer may be, but is not limited to, a polytetrafluoroethylene (PTFE) layer. The buffer layer can protect the light emitting unit 70 and prevent the surface of the light emitting unit 70 from damages when the hot-pressing head hot-presses the light emitting unit 70.

At S4, the first adhesive layer 30 and the second adhesive layer 50 are cured, i.e., main cured, where the multiple light emitting units 70 are electrically connected with the driving substrate 10 through the conductive particles 31.

Specifically, the first adhesive layer 30 and the second adhesive layer 50 are cured as follows, where the multiple light emitting units 70 are electrically connected with the driving substrate 10 through the conductive particles 31. The multiple light emitting units 70 are pressed under a third condition, to fill the gaps between the multiple light emitting units 70 with the first adhesive layer 30 and the second adhesive layer 50, and cure the first adhesive layer 30 and the second adhesive layer 50, where the driving substrate 10 is electrically connected with the multiple light emitting units 70 through the conductive particles 31.

Optionally, the third condition includes a third temperature and a third pressure, or the third condition includes an action of light and a third pressure. The third pressure is between 4.5 MPa and 7 MPa.

Optionally, the action of light may be an action of UV light. In this case, the first adhesive layer 30 and the second adhesive layer 50 may be made of a light-cured material.

Optionally, the third temperature is between 150° C. and 220° C., i.e., the third temperature, may be any temperature between 150° C. and 220° C., such as 150° C., 160° C., 170° C., 180° C., 190° C., 200° C., 210° C., or 220° C.

Optionally, the third pressure is between 4.5 MPa and 7 MPa, i.e., the third pressure may be any pressure between 4.5 MPa and 7 MPa, such as 4.5 MPa, 4.8 MPa, 5.0 MPa, 5.5 MPa, 6.0 MPa, 6.5 MPa, or 7 MPa.

Under the third temperature, the second adhesive layer 50 gradually transfers from the B-stage to be fully cured, and the second adhesive layer 50 still has a slight fluidity before fully cured. In this case, the first adhesive layer 30 fully transfers to be liquid. The P electrode 71 and the N electrode 73 of the light emitting unit 70 are gradually embedded into the liquid first adhesive layer 30 when the hot-pressing head presses down. The squeezed first adhesive layer 30 flows to the gaps between the light emitting units 70 to fill a retaining wall. The P electrode 71 and the N electrode 73 of the light emitting unit 70 are in contact with the conductive particles 31 and squeeze the conductive particles 31 under an action of the third pressure. As such, the P electrode 71 of the light emitting unit 70 can be bonded with the first electrode 11 of the driving substrate 10, and the N electrode 73 of the light emitting unit 70 can be bonded with the second electrode 13 of the driving substrate 10. During this process, the first adhesive layer 30 is cured and forms a connection portion 30 of the display panel 100, and the second adhesive layer 50 is cured and forms a light-blocking portion 50 of the display panel 100.

Optionally, during the curing, time for a temperature to rise to 90% of the third temperature is less than or equal to half of total time for the curing. For example, the time for the temperature to rise to 90% of the third temperature is less than or equal to 5 seconds when the total time for the curing is 10 seconds. For another example, the time for the temperature to rise to 90% of the third temperature is less than or equal to 2 seconds when the total time for the curing is 5 seconds. As such, the P electrode 71 and the N electrode 73 may have an improved ability to trap the conductive particles 31, to be better electrically connected with the driving substrate 10. If the rising of the temperature is too slow, the P electrode 71 and the N electrode 73 may trap less conductive particles 31, which influences conductivity.

Optionally, in some implementations, during hot-pressing for curing, a buffer layer is disposed on the surface of the hot-pressing head facing the multiple light emitting units 70. Alternatively, a buffer layer is disposed on the surface of the multiple light emitting units 70 away from the driving substrate 10.

Optionally, the buffer layer may be, but is not limited to, a PTFE layer. The buffer layer can protect the light emitting unit 70 and prevent the surface of the light emitting unit 70 from damages when the hot-pressing head hot-presses the light emitting unit 70.

Optionally, the second adhesive layer 50 of the manufactured display panel 100 has a thickness between 4 μm and 7 μm, which is beneficial to prevent crosstalk of lateral light emitted by different light emitting units.

The method for manufacturing the display panel 100 in the present disclosure includes the following. The first adhesive layer 30 and the second adhesive layer 50 are disposed sequentially on the surface of the driving substrate 10, and the first adhesive layer 30 includes the conductive particles 31. The multiple light emitting units 70 arranged in an array are adhered to one side of the second adhesive layer 50 away from the driving substrate 10. The second adhesive layer 50 is semi-cured. The first adhesive layer 30 and the second adhesive layer 50 are cured, where the multiple light emitting units 70 are electrically connected with the driving substrate 10 through the conductive particles 31. As such, an adhesiveness between the light emitting unit 70 and the driving substrate 10 can be increased, such that the light emitting unit 70 can be better aligned with an electrode on the driving substrate 10 during mass transfer, thereby increasing accuracy of the position of the light emitting unit 70 and thus a yield of display panel 100 manufacturing. At the same time, a color cast risk may be effectively decreased by using a light-blocking portion 50 formed between the light emitting units 70 by the second adhesive layer 50.

The following will describe the technical solutions of the present disclosure in detail with implementations.

In some implementations, a method for manufacturing a display panel 100 is provided in the present disclosure. The method includes the following. A driving substrate 10 is disposed on a supporting stage 101. An ACF layer is adhered to a surface of the driving substrate 10 where a first electrode 11 and a second electrode 13 are disposed at 75° C. by using a pressing head with a pressure of 0.8 MPa, to form a first adhesive layer 30. The first adhesive layer 30 includes conductive particles 31. An epoxy resin added with carbon black and a curing agent is sprayed to a surface of the first adhesive layer 30 away from the driving substrate 10 and is UV pre-cured, to form a second adhesive layer 50. Multiple light emitting units 70 are arranged in an array on a surface of the second adhesive layer 50 away from the driving substrate 10 by using mass transfer. Each of the multiple light emitting units 70 has a P electrode 71 and an N electrode 73. For each light emitting unit 70, the P electrode 71 has a position corresponding to the first electrode 11, and the N electrode 73 has a position corresponding to the second electrode 13. The multiple light emitting units 70 are pressed down at a uniform speed at 100° C. by using a hot-pressing head with a pressure of 1.0 MPa. As such, the second adhesive layer 50 is semi-cured and in a B-stage, thus the second adhesive layer 50 is squeezed into gaps between the multiple light emitting units 70. The multiple light emitting units 70 are pressed down again at a uniform speed at 200° C. by using a hot-pressing head with a pressure of 5 MPa. As such, the P electrodes 71 and the N electrodes 73 of the multiple light emitting units 70 squeeze the conductive particles 31 and are electrically connected with the first electrodes 11 and the second electrodes 13 of the driving substrate 10 respectively through the conductive particles 31. At the same time, the first adhesive layer 30 is also squeezed into the gaps between the multiple light emitting units 70, and the second adhesive layer 50 is also squeezed into the gaps between the multiple light emitting units 70 to form a light-blocking portion 50.

In some other implementations, a method for manufacturing a display panel 100 is provided in the present disclosure. The method includes the following. A driving substrate 10 is disposed on a supporting stage 101. An ACF layer is adhered to a surface of the driving substrate 10 where a first electrode 11 and a second electrode 13 are disposed at 80° C. by using a pressing head with a pressure of 0.5 MPa, to form a first adhesive layer 30. The first adhesive layer 30 includes conductive particles 31. An epoxy resin added with black dye and a curing agent is sprayed to a surface of the first adhesive layer 30 away from the driving substrate 10 and is UV pre-cured, to form a second adhesive layer 50. Multiple light emitting units 70 are arranged in an array on a surface of the second adhesive layer 50 away from the driving substrate 10 by using mass transfer. Each of the multiple light emitting units 70 has a P electrode 71 and an N electrode 73. For each light emitting unit 70, the P electrode 71 has a position corresponding to the first electrode 11, and the N electrode 73 has a position corresponding to the second electrode 13. The multiple light emitting units 70 are pressed down at a uniform speed at 90° C. by using a hot-pressing head with a pressure of 1.5 MPa. As such, the second adhesive layer 50 is semi-cured and in a B-stage, thus the second adhesive layer 50 is squeezed into gaps between the multiple light emitting units 70. The multiple light emitting units 70 are pressed down again at a uniform speed at 150° C. by using a hot-pressing head with a pressure of 7 MPa. As such, the P electrodes 71 and the N electrodes 73 of the multiple light emitting units 70 squeeze the conductive particles 31 and are electrically connected with the first electrodes 11 and the second electrodes 13 respectively through the conductive particles 31. At the same time, the first adhesive layer 30 is also squeezed into the gaps between the multiple light emitting units 70, and the second adhesive layer 50 is also squeezed into the gaps between the multiple light emitting units 70 to form a light-blocking portion 50.

In some implementations, a method for manufacturing a display panel 100 is provided in the present disclosure. The method includes the following. A driving substrate 10 is disposed on a supporting stage 101. An ACF layer is adhered to a surface of the driving substrate 10 where a first electrode 11 and a second electrode 13 are disposed at 60° C. by using a pressing head with a pressure of 1.0 MPa, to form a first adhesive layer 30. The first adhesive layer 30 includes conductive particles 31. An epoxy resin added with black dye and a curing agent is sprayed to a surface of the first adhesive layer 30 away from the driving substrate 10 and is UV pre-cured, to form a second adhesive layer 50. Multiple light emitting units 70 are arranged in an array on a surface of the second adhesive layer 50 away from the driving substrate 10 by using mass transfer. Each of the multiple light emitting units 70 has a P electrode 71 and an N electrode 73. For each light emitting unit 70, the P electrode 71 has a position corresponding to the first electrode 11, and the N electrode 73 has a position corresponding to the second electrode 13. The multiple light emitting units 70 are pressed down at a uniform speed at 120° C. by using a hot-pressing head with a pressure of 0.8 MPa. As such, the second adhesive layer 50 is semi-cured and in a B-stage, thus the second adhesive layer 50 is squeezed into gaps between the multiple light emitting units 70. The multiple light emitting units 70 are pressed down again at a uniform speed at 220° C. by using a hot-pressing head with a pressure of 5.5 MPa. As such, the P electrodes 71 and the N electrodes 73 of the multiple light emitting units 70 squeeze the conductive particles 31 and are electrically connected with the first electrodes 11 and the second electrodes 13 of the driving substrate 10 respectively through the conductive particles 31. At the same time, the first adhesive layer 30 is also squeezed into the gaps between the multiple light emitting units 70, and the second adhesive layer 50 is also squeezed into the gaps between the multiple light emitting units 70 to form a light-blocking portion 50.

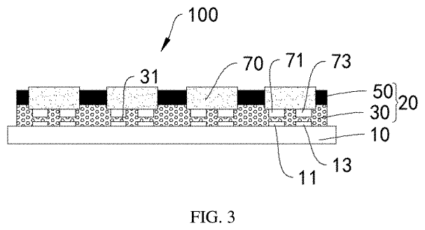

Referring to FIG. 3, a display panel 100 is further provided in implementations of the present disclosure. The display panel 100 includes a driving substrate 10, multiple light emitting units 70 arranged in an array on one side of the driving substrate 10, and a shading structure 20 located at a same side of the driving substrate 10 as the multiple light emitting units 70. The shading structure 20 is located in gaps between the multiple light emitting units 70 and disposed around each of the multiple light emitting units 70. The shading structure 20 includes conductive particles 31, and each of the multiple light emitting units 70 is electrically connected with the driving substrate 10 through the conductive particles 31.

Optionally, electrical connection between the multiple light emitting units 70 and the driving substrate 10 is completed in a same process as forming the shading structure 20, which can further simplify manufacturing of the shading structure 20.

In the present disclosure, the bonding between the light emitting units 70 and the driving substrate 10 of the display panel 100 is achieved through an electrical connection via the conductive particles 31 of the shading structure 20, such that the shading structure 20 is formed when the light emitting units 70 are bonded, thereby simplifying a manufacturing process of the display panel 100.

Optionally, in some implementations, the shading structure 20 includes a connection portion 30 and a light-blocking portion 50 connected with the connection portion 30. The connection portion 30 is disposed close to the driving substrate 10. The light-blocking portion 50 is disposed away from the driving substrate 10. The connection portion 30 includes the conductive particles 31 and has anisotropic conductivity. The light-blocking portion 50 has a light-blocking property.

Optionally, in some implementations, the light-blocking portion 50 has a thickness between 4 μm and 7 μm, i.e., the thickness of the light-blocking portion 50 may have any value between 4 μm and 7 μm, such as 4 μm, 4.5 μm, 5 μm, 5.5 μm, 6 μm, 6.5 μm, or 7 μm.

Optionally, the light-blocking portion 50 is formed by the cured second adhesive layer 50 in the method for manufacturing a display panel in the present disclosure. Reference can be made to the above method implementations for details, which will not be repeated herein.

Optionally, in some implementations, the connection portion 30 has a thickness between 3 μm and 8 μm, i.e., the thickness of the connection portion 30 may have any value between 3 μm and 8 μm, such as 3 μm, 3.5 μm, 4 μm, 4.5 μm, 5 μm, 5.5 μm, 6 μm, 6.5 μm, 7 μm, 7.5 μm, or 8 μm.

Optionally, the connection portion 30 is formed by the cured first adhesive layer 30 in the method for manufacturing a display panel in the present disclosure. Reference can be made to the above method implementations for details, which will not be repeated herein.

Optionally, in some implementations, the conductive particle 31 has a particle diameter between 3 μm and 5 μm, i.e., the particle diameter of the conductive particle 31 may have any value between 3 μm and 5 μm, such as 3 μm, 3.5 μm, 4 μm, 4.5 μm, or 5 μm.

Optionally, in some implementations, the display panel 100 is manufactured according to the method for manufacturing a display panel in implementations of the present disclosure.

Reference can be made to the above method implementations for details, which will not be repeated herein.

The above describes only some implementations of the present disclosure and is not intended to limit the present disclosure. Any modification, equivalent replacement, and improvement made within the spirit and principles of the present disclosure should fall into the scope of the present disclosure.

In descriptions of this specification, descriptions with reference to terms “one implementation”, “some implementations”, “exemplary implementations”, “examples”, “specific examples”, or “some examples”, etc. mean that specific features, structures, materials, or characteristics described in combination with implementations or examples are included in at least one implementation or example of the present application. In this specification, a schematic representation of above-mentioned terms does not necessarily refer to the same implementation or example. Moreover, specific features, structures, materials, or characteristics described can be combined in an appropriate manner in any one or more implementations or examples.

The above describes only some implementations of the present disclosure and is not intended to limit the present disclosure. Any modification, equivalent replacement, and improvement made within the spirit and principles of the present disclosure should fall into the scope of the present disclosure.

What is claimed is:

1. A method for manufacturing a display panel, comprising:
disposing a first adhesive layer and a second adhesive layer sequentially on a surface of a driving substrate, the first adhesive layer comprising conductive particles;
adhering a plurality of light emitting units arranged in an array to one side of the second adhesive layer away from the driving substrate;
semi-curing the second adhesive layer; and
curing the first adhesive layer and the second adhesive layer, wherein the plurality of light emitting units are electrically connected with the driving substrate through the conductive particles.

2. The method of claim 1, wherein disposing the first adhesive layer and the second adhesive layer sequentially on the surface of the driving substrate comprises:
pressing, under a first condition, the first adhesive layer onto a surface of the driving substrate on which electrodes are provided; and
applying an adhesive to a surface of the first adhesive layer away from the driving substrate and pre-curing the adhesive, to form the second adhesive layer.

3. The method of claim 2, wherein
the first condition comprises a first temperature and a first pressure, the first temperature is between 60° C. and 80° C., and the first pressure is between 0.5 MPa and 1 MPa; or
the first condition comprises an action of light and a first pressure, and the first pressure is between 0.5 MPa and 1 MPa.

4. The method of claim 1, wherein semi-curing the second adhesive layer comprises:
pressing the plurality of light emitting units under a second condition, to semi-cure the second adhesive layer.

5. The method of claim 4, wherein
the second condition comprises a second temperature and a second pressure, the second temperature is between 80° C. and 120° C., and the second pressure is between 0.8 MPa and 1.5 MPa; or
the second condition comprises an action of light and a second pressure, and the second pressure is between 0.8 MPa and 1.5 MPa.

6. The method of claim 1, wherein semi-curing the second adhesive layer comprises:
hot-pressing the plurality of light emitting units with a second pressure at a temperature where the first adhesive layer is in a rubbery state, to fill gaps between the plurality of light emitting units with the second adhesive layer and form a semi-cured second adhesive layer.

7. The method of claim 1, wherein curing the first adhesive layer and the second adhesive layer comprises:
pressing, the plurality of light emitting units under a third condition, to fill gaps between the plurality of light emitting units with the first adhesive layer and the second adhesive layer, and cure the first adhesive layer and the second adhesive layer.

8. The method of claim 7, wherein
the third condition comprises a third temperature and a third pressure, the third temperature is between 150° C. and 220° C., and the third pressure is between 4.5 MPa and 7 MPa; or
the third condition comprises an action of light and a third pressure, and the third pressure is between 4.5 MPa-7 MPa.

9. The method of claim 7, wherein during the curing, time for a temperature to rise to 90% of a third temperature is less than or equal to half of total time for the curing.

10. The method of claim 1, wherein the second adhesive layer has a light-blocking property, and the second adhesive layer has a melting temperature lower than the first adhesive layer.

11. A display panel, comprising:
a driving substrate;
a plurality of light emitting units arranged in an array on one side of the driving substrate; and
a shading structure located at a same side of the driving substrate as the plurality of light emitting units, wherein the shading structure is located in gaps between the plurality of light emitting units and disposed around each of the plurality of light emitting units, wherein
the shading structure comprises conductive particles, and each of the plurality of light emitting units is electrically connected with the driving substrate through the conductive particles.

12. The display panel of claim 11, wherein the shading structure comprises:
a connection portion; and
a light-blocking portion connected with the connection portion.

13. The display panel of claim 12, wherein the light-blocking portion has a thickness between 4 μm and 7 μm.

14. The display panel of claim 12, wherein the connection portion has a thickness between 3 μm and 8 μm.

15. The display panel of claim 11, wherein electrical connection between the plurality of light emitting units and the driving substrate is completed in a same process as forming the shading structure.

16. The display panel of claim 11, wherein the display panel is manufactured according to the method of claim 1.

17. The display panel of claim 11, wherein each of the conductive particles has a particle diameter between 3 μm and 5 μm.

18. The display panel of claim 11, wherein each of the light emitting units is a micro-LED or a mini-LED.

19. The display panel of claim 12, wherein the connection portion is disposed close to the driving substrate, and the light-blocking portion is disposed away from the driving substrate.

20. The display panel of claim 12, wherein the connection portion comprises the conductive particles and has anisotropic conductivity, and the light-blocking portion has a light-blocking property.
